(19) United States
(12) Patent Application Publication
(10) Pub. No.: US 2006/0231847 A1
(43) Pub. Date: Oct. 19, 2006

(54) Multiple-wavelength light emitting diode and its light emitting chip structure

(75) Inventors: Ming-Shun Lee, Taipei (TW); Ping-Ru Sung, Taipei (TW); Chang-Wei Ho, Taipei (TW)

Correspondence Address: TROXELL LAW OFFICE PLLC;SUITE 1404, 5205 LEESBURG PIKE, FALLS CHURCH, VA, 22041, US

(73) Assignee: Taiwan Oasis Technology Co., Ltd.

(21) Appl. No.: 11/106,443

(22) Filed: Apr. 15, 2005

(51) Int. Cl. H01L 31/12

(52) U.S. Cl. 257/82; 257/E33.072

(57) ABSTRACT

The present invention discloses a multiple-wavelength light emitting diode that includes a fluorescent layer with a predetermined wavelength disposed at the bottom of the light emitting diode, such that a light emitting chip can be fixed onto a carrier and connected in parallel with the circuit of the light emitting chip by a gold wire. The light emitting chip is packaged by a package material to constitute a light emitting diode capable of combining the light source of the light emitting chip with the wavelength of the fluorescent layer, so as to produces the desired light color.

### BACKGROUND OF THE INVENTION

1. Field of the Invention

The present invention relates to a color light performance technology of a light emitting diode, and more particularly to a light emitting diode and its light emitting chip structure capable of producing correct light colors and enhance brightness performance effectively.

2. Description of the Related Art

In general, a basic structure of a light emitting diode includes a related package material to package a light emitting chip, and a gold wire used to electrically connect the light emitting chip with related circuits. The light emitting chip produces a light source after the light emitting chip is electrically connected. The light source is projected outward from the package material and further combined with the wavelength of a fluorescent material in the package material to produce a desired light color.

Referring to FIG. 1, the present common traditional light emitting diode structure directly adopts a substrate 10 as the carrier of a light emitting chip 20. The light emitting diode of this type implants a recessed base 11 into the surface of the substrate 10, and the recessed base 11 fixes the light emitting chip 20 in position and provides a space for filling the package material 30. In practical applications, a bonding material 40 is coated between the light emitting chip 20 and the substrate 10 (or a carrier with similar function) to achieve the purpose of fixing the light emitting chip 20. However, such arrangement implants some regions at the bottom of the light emitting chip 20 into the bonding material 40, and thus reducing the overall brightness performance of the light emitting diode. Furthermore, it is not easy to control the composition of the bonding material 40, the coating area and the coating quantity, although the bonding material 40 is mixed with a fluorescent material to combine the light source of the light emitting chip with the wavelength of the fluorescent material to produce expected light colors, and thus it is unable to precisely control the quality of light colors for the overall performance of the light emitting diode.

### SUMMARY OF THE INVENTION

In view of the foregoing shortcomings of the prior art, the inventor of the present invention based on years of experience in the related field to conduct extensive researches and experiments to overcome the aforementioned shortcomings and finally invented the present invention.

It is a primary objective of the present invention to provide a multiple-wavelength light emitting diode comprising a fluorescent layer with a predetermined wavelength disposed at the bottom of the light emitting diode, such that a light emitting chip can be fixed onto a carrier and connected in parallel with the circuit of the light emitting chip. The light emitting chip is packaged by a package material to constitute a light emitting diode that combines the light source of the light emitting chip with the wavelength of the fluorescent layer, so as to produces the desired light color. Since the fluorescent layer is fixed onto the bottom of the light emitting diode in advance, therefore the coating area and the coating quantity can be controlled effectively and the quality of light color produced by the fluorescent layer can be controlled precisely. Even more, a reflective material installed at the lowest fluorescent layer under the light emitting chip can effectively enhance the brightness performance of the light emitting diode.

### BRIEF DESCRIPTION OF THE DRAWINGS

FIG. 1 is a cross-sectional view of the structure of a prior art light emitting diode;

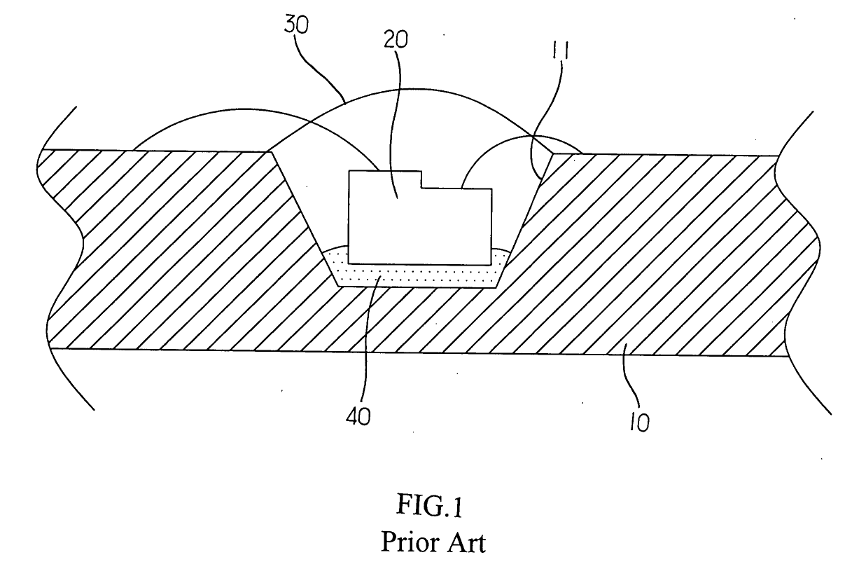

FIG. 2 is a perspective view of a light emitting diode according to a first preferred embodiment of the present invention;

FIG. 3 is a cross-sectional view of a light emitting diode according to a first preferred embodiment of the present invention;

FIG. 4 is a cross-sectional view of a light emitting diode according to a second preferred embodiment of the present invention;

FIG. 5 is a cross-sectional view of a light emitting diode according to a third preferred embodiment of the present invention;

FIG. 6 is a cross-sectional view of a light emitting diode according to a fourth preferred embodiment of the present invention;

FIG. 7 is a cross-sectional view of a light emitting diode according to a fifth preferred embodiment of the present invention; and

FIG. 8 is a cross-sectional view of a light emitting diode according to an eighth preferred embodiment of the present invention.

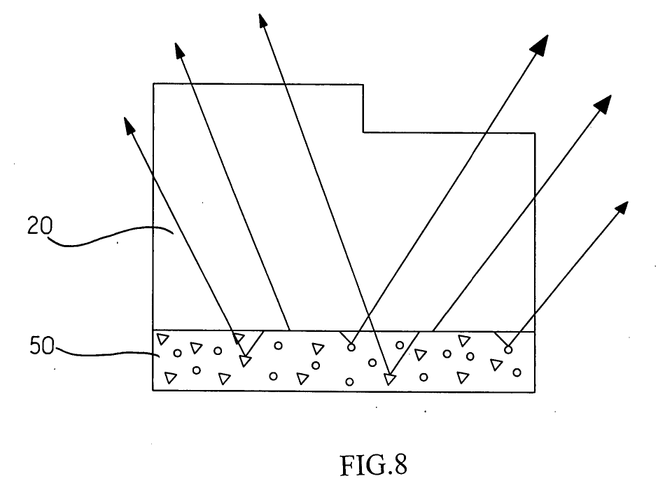

### DETAILED DESCRIPTION OF THE PREFERRED EMBODIMENTS

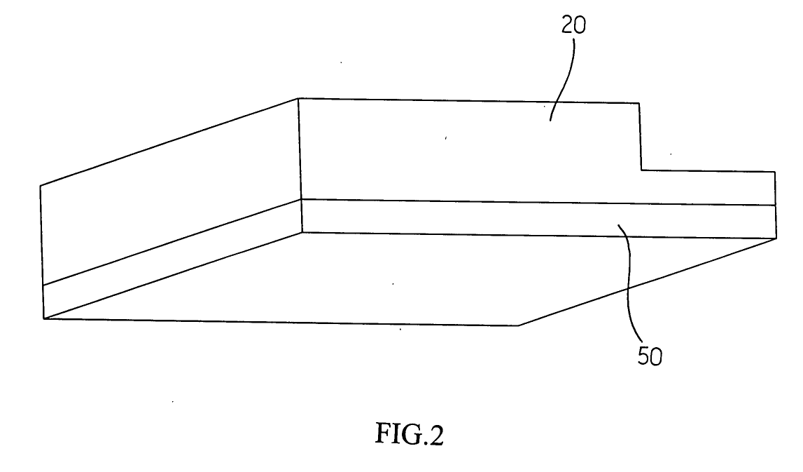

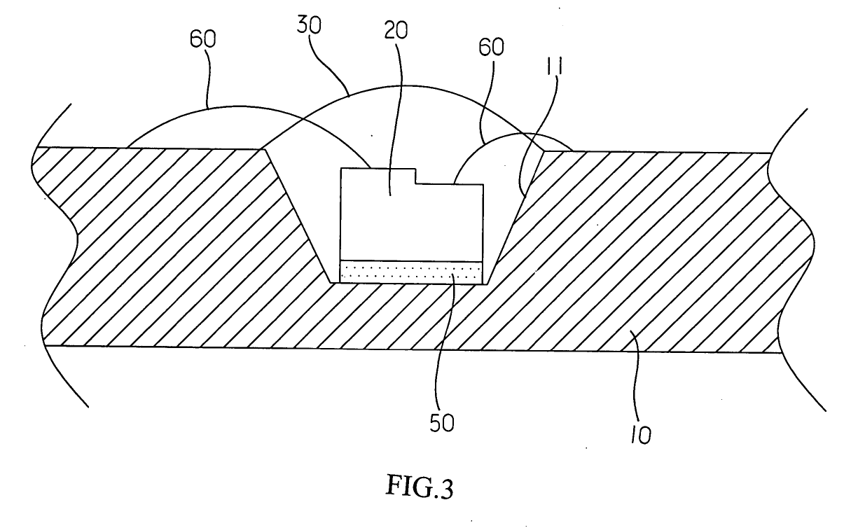

The multiple-wavelength light emitting diode in accordance with the present invention provides a light emitting diode and its light emitting chip structure capable of producing a correct light color and effectively enhancing the brightness performance. In FIG. 2, the light emitting chip 20 includes a fluorescent layer 50 having a predetermined wavelength and disposed at the bottom of the light emitting chip 20, and the fluorescent layer 50 could be made of a single fluorescent power or made by mixing two or more fluorescent powders according to a predetermined proportion. In FIG. 3, the light emitting chip 20 is fixed into a predetermined space (or a carrier having a similar function) on the substrate 10 and the circuit of the light emitting chip 20 is connected in parallel by a gold wire 60. The light emitting chip 20 is packaged by a package material 30, so that the light source of the light emitting chip 20 can be combined with the wavelength of the fluorescent layer 50, so as to produce the expected light color.

Since the fluorescent layer 50 is fixed onto the bottom of the light emitting chip 20 in advance, therefore the coating area and the coating quantity can be controlled effectively and the quality of the light color produced by the fluorescent layer can be controlled precisely.

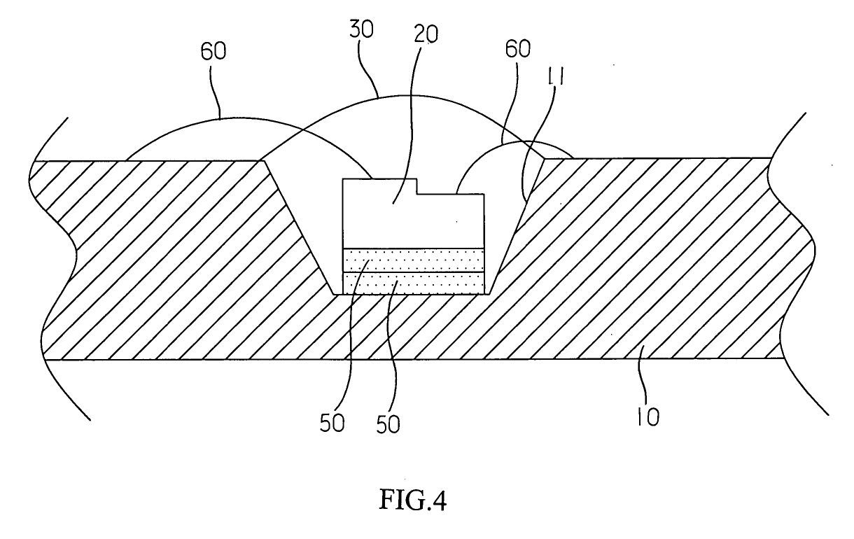

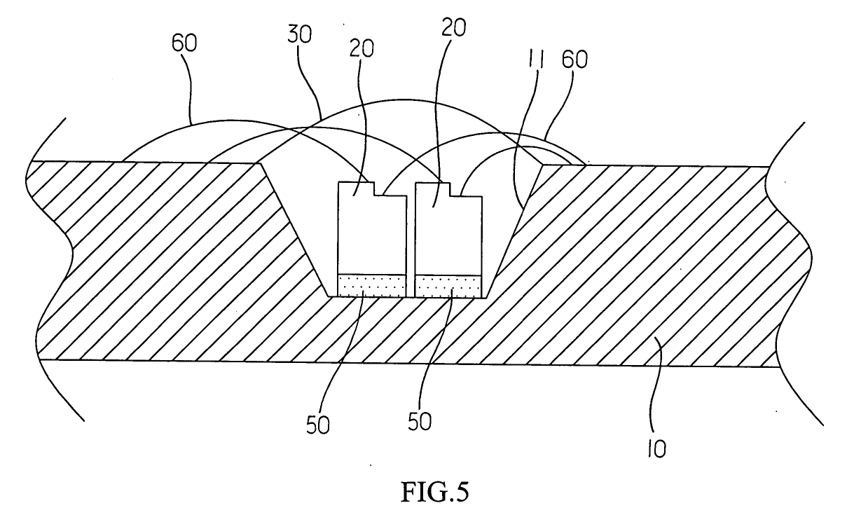

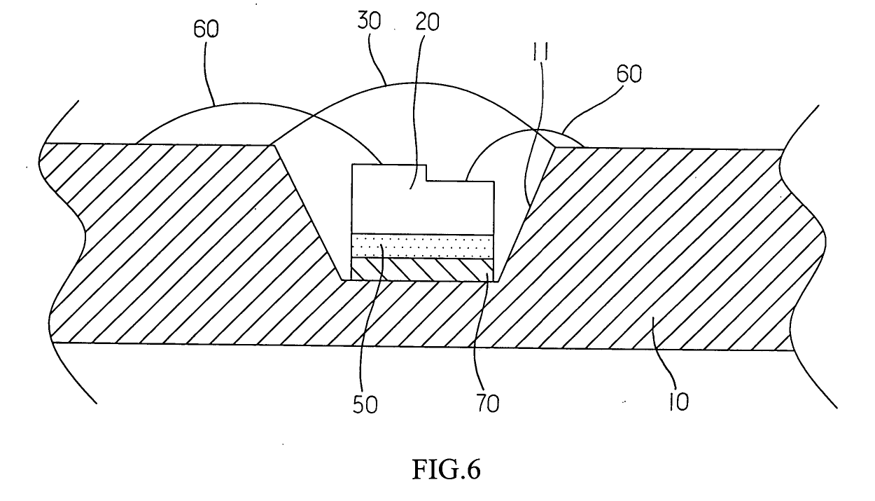

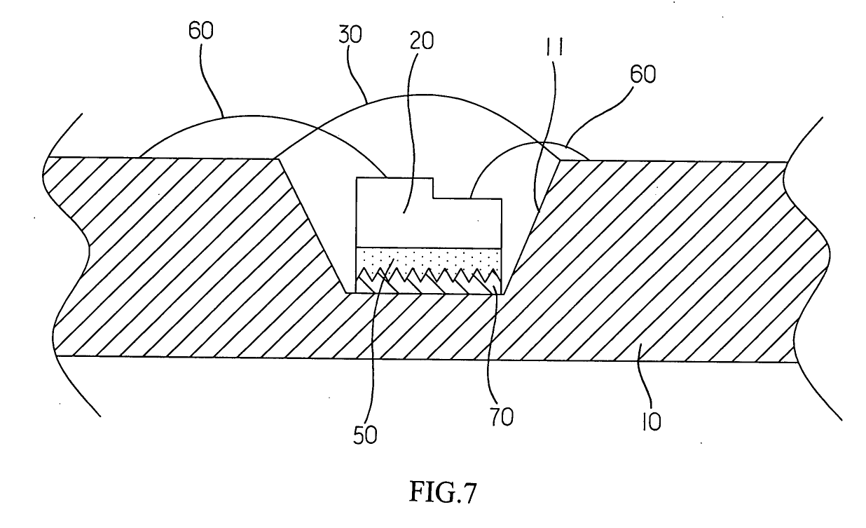

In practical applications, the multi-wavelength light emitting diode in accordance with the present invention is shown in FIG. 4. A plurality of fluorescent layers 50 having a predetermined wavelength is installed at the bottom of each light emitting chip 29 to constitute the combination of multi-wavelengths to produce the expected light color. Of course, a plurality of light emitting chips 20 could be installed in a light emitting diode as shown in FIG. 5, and a fluorescent layer 50 having a predetermined wavelength is installed at the bottom of each light emitting chip 20 or a fluorescent material having a predetermined wavelength is mixed in a predetermined proportion into the package material 30, so as to constitute more combinations of multiple wavelengths and produce the expected light color. Even more, a reflective material 70 is installed at the lowest fluorescent layer 50 under the light emitting chip 20 as shown in FIG. 6 to enhance the brightness performance of the light emitting diode, and the reflective material 70 is a natural crystal in the shape of a slab disposed at the bottom of the fluorescent layer 50 or a natural crystal having predetermined reflective lines on its surface as shown in FIG. 7. Of course, the reflective material 70 could have reflective particles directly mixed into the fluorescent layer 50 to project the light source of the light emitting diode in a predetermined direction, so as to enhance the brightness performance of the light emitting diode.

In summation of the above description, the present invention provides light emitting diode and its light emitting chip structure capable of producing a correct light color and effectively enhancing the brightness performance, and herein complies with the patent application requirements and is submitted for patent application. However, the description and its accompanied drawings are used for describing preferred embodiments of the present invention, and it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A chip, comprising:
a fluorescent layer, having a predetermined wavelength and disposed at the bottom of a light emitting chip.

2. A chip, comprising:
at least two fluorescent layers, having a predetermined wavelength and disposed at the bottom of a light emitting chip; and
a reflective material, disposed at the bottom of the lowest layer of said fluorescent layers.

3. The chip of claim 2, wherein said reflective material is a natural crystal having predetermined reflective lines on its surface or in the shape of a slab.

4. The chip of claim 2, wherein said reflective material includes reflective particles mixed in said fluorescent layer.

5. The chip of claim 1, wherein said fluorescent layer is made of a single fluorescent powder or made by mixing at least two fluorescent powders according to a predetermined proportion.

6. A light emitting diode, comprising:
at least one light emitting chip, installed on a carrier;
a gold wire, for connecting a circuit of said light emitting chip in parallel;
a package material, for packaging said light emitting chip; and
a fluorescent layer, having a predetermined wavelength and disposed at the bottom of said each light emitting chip.

7. The light emitting diode of claim 6, wherein said package material is mixed in a predetermined proportion with at least one fluorescent material having a predetermined wavelength.

8. A light emitting diode, comprising:
at least one light emitting chip, installed on a carrier;
a gold wire, for connecting a circuit of said light emitting chip in parallel;
a package material, for packaging said light emitting chip;
a fluorescent layer, having a predetermined wavelength and disposed at the bottom of said each light emitting chip; and
a reflective material disposed at the lowest fluorescent layer of said light emitting chip.

9. The light emitting diode of claim 8, wherein said reflective material is a natural crystal in the shape of a slab or having predetermined lines on the surface of said natural crystal.

10. The light emitting diode of claim 8, wherein said reflective material comprises reflective particles mixed in said fluorescent layer.
